(19) United States
(12) Patent Application Publication
(10) Pub. No.: US 2026/0173629 A1
(43) Pub. Date: Jun. 18, 2026

(54) DISPLAY DEVICE

(71) Applicant: AUO Corporation, Hsinchu City (TW)

(72) Inventors: Chia-Ting Hsieh, Hsinchu City (TW); Tzu-Chin Huang, Hsinchu City (TW); Chan-Jui Liu, Hsinchu City (TW)

(73) Assignee: AUO Corporation, Hsinchu City (TW)

(21) Appl. No.: 19/262,118

(22) Filed: Jul. 8, 2025

(30) Foreign Application Priority Data
Dec. 16, 2024 (TW) 113148943

(51) Int. Cl. H10H 29/855

(52) U.S. Cl. CPC H10H 29/855

(57) ABSTRACT

A display device including a substrate and a plurality of display units thereon is provided. The display unit includes a light-emitting diode, a first insulating layer and a second insulating layer. The light-emitting diode includes a first semiconductor layer, a light-emitting layer and a second semiconductor layer in sequence. The first insulating layer and the second insulating layer surround the light-emitting diode, wherein the first insulating layer is disposed between the substrate and the second insulating layer. A distance between a top surface of the second semiconductor layer and the substrate is greater than a distance between a top surface of the first insulating layer and the substrate, and is less than a distance between a top surface of the second insulating layer and the substrate.

### CROSS-REFERENCE TO RELATED APPLICATION

This application claims the priority benefit of Taiwan application serial no. 113148943, filed on Dec. 16, 2024. The entirety of the above-mentioned patent application is hereby incorporated by reference herein and made a part of this specification.

### BACKGROUND

### Technical Field

The disclosure relates to a display device.

### Description of Related Art

In existing light-emitting diode (LED) displays, an insulating layer is used to surround the light-emitting diodes to facilitate wire bonding. However, light emitted from the light-emitting diodes is susceptible to total internal reflection at the surface of the insulating layer, resulting in insufficient light extraction efficiency of the light-emitting diodes.

### SUMMARY

A display device is provided in the disclosure. The display device includes a light-emitting diode, which has high light extraction efficiency.

According to an embodiment of the disclosure, a display device is provided, including a substrate and a plurality of display units disposed on the substrate. At least one display unit among the display units includes a light-emitting diode, a first insulating layer and a second insulating layer. The light-emitting diode includes a first semiconductor layer, a light-emitting layer and a second semiconductor layer sequentially disposed along a first direction away from the substrate. The first insulating layer surrounds the light-emitting diode. The second insulating layer surrounds the light-emitting diode, in which the first insulating layer is disposed between the substrate and the second insulating layer. A first distance between a top surface of the second semiconductor layer and the substrate is greater than a second distance between a top surface of the first insulating layer and the substrate, and is less than a third distance between a top surface of the second insulating layer and the substrate.

According to an embodiment of the disclosure, a display device is provided, including a substrate and a plurality of display units disposed on the substrate. At least one display unit among the display units includes a light-emitting diode, a first insulating layer and a second insulating layer. The light-emitting diode includes a first semiconductor layer, a light-emitting layer and a second semiconductor layer sequentially disposed along a first direction away from the substrate. The first insulating layer surrounds the light-emitting diode. The second insulating layer surrounds the light-emitting diode, in which the first insulating layer is disposed between the substrate and the second insulating layer. A first distance between a top surface of the second semiconductor layer and the substrate is greater than a second distance between a top surface of the first insulating layer and the substrate, and is less than a third distance between a top surface of the second insulating layer and the substrate. The second insulating layer is a patterned structure, and a partial top surface of the first insulating layer is exposed by the second insulating layer. The second insulating layer directly contacts the top surface of the first insulating layer. A refractive index of the second insulating layer is less than a refractive index of the first insulating layer and is greater than 1.

Based on the above, in the display device provided according to the embodiment of the disclosure, the first insulating layer and the second insulating layer are configured to directly contact the side surface of the light-emitting diode to avoid total internal reflection at the light-emitting surface of the light-emitting diode.

In order to make the above-mentioned features and advantages of the disclosure comprehensible, embodiments accompanied with drawings are described in detail below.

### BRIEF DESCRIPTION OF THE DRAWINGS

FIG. 1A to FIG. 1C are schematic diagrams of display devices according to some embodiments of the disclosure.

FIG. 2 is a schematic diagram showing a display device according to a first embodiment of the disclosure.

FIG. 3 is a schematic diagram showing a display device according to a second embodiment of the disclosure.

FIG. 4 is a schematic diagram showing a display device according to a third embodiment of the disclosure.

### DETAILED DESCRIPTION OF DISCLOSED EMBODIMENTS

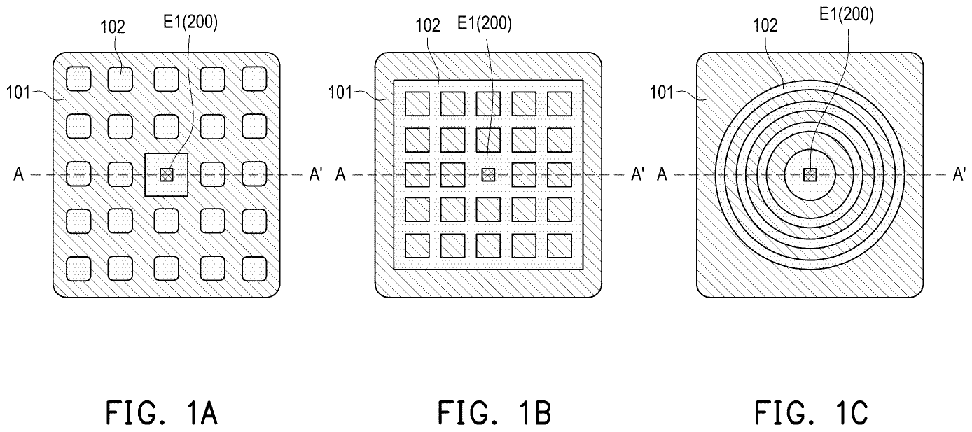

Referring to FIG. 1A to FIG. 1C, FIG. 1A to FIG. 1C are schematic diagrams of display devices according to some embodiments of the disclosure.

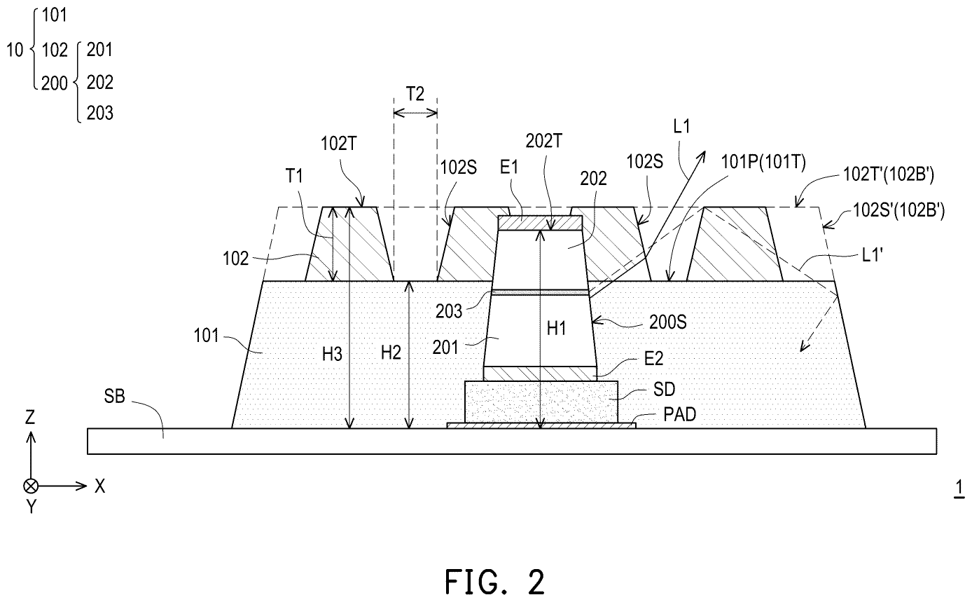

Referring to FIG. 2, FIG. 2 is a schematic diagram showing a display device according to a first embodiment of the disclosure. FIG. 2 may be regarded as a cross-sectional schematic diagram along line segment AA′ of FIG. 1A, FIG. 1B or FIG. 1C.

The display device 1 includes a substrate SB and one or more display units 10 disposed on the substrate SB. The substrate SB is disposed on an X-Y plane. The display unit 10 includes a light-emitting diode 200, a first insulating layer 101 and a second insulating layer 102. In some embodiments, the first insulating layer 101 and the second insulating layer 102 may include organic, inorganic, or organic and inorganic composite insulating materials. The light-emitting diode 200 includes a first semiconductor layer 201, a light-emitting layer 203, and a second semiconductor layer 202 sequentially disposed along a Z direction, in which the X direction, the Y direction, and the Z direction are perpendicular to each other. The first insulating layer 101 and the second insulating layer 102 directly contact and surround the light-emitting diode 200. A first distance H1 is between a top surface 202T of the second semiconductor layer 202 and the substrate SB, a second distance H2 is between a top surface 101T of the first insulating layer 101 and the substrate SB, and a third distance H3 is between a top surface 102T of the second insulating layer 102 and the substrate SB. The first distance H1 is greater than the second distance H2 and less than the third distance H3. By directly contacting the side surface 200S of the light-emitting diode 200 (i.e., the light-emitting surface 200S of the light-emitting diode 200) with the first insulating layer 101 and the second insulating layer 102, it is possible to avoid a situation where total internal reflection occurs on the light-emitting surface 200S due to exposure to air, which would result in low light extraction efficiency of the light-emitting diode 200.

In some embodiments, the second insulating layer 102 directly contacts the top surface 101T of the first insulating layer 101, and the refractive index of the second insulating layer 102 is different from the refractive index of the first insulating layer 101. In some embodiments, the refractive index of the second insulating layer 102 is less than the refractive index of the first insulating layer 101 and is greater than 1. In other words, the refractive indices of the first insulating layer 101, the second insulating layer 102 and the air gradually decrease in that order. Compared with a comparative example in which the second insulating layer 102 is not provided, the display unit 10 of the embodiment of the disclosure may improve the light extraction efficiency of the light-emitting diode 200 by utilizing the interface between the first insulating layer 101 and the second insulating layer 102.

As shown in FIG. 2, the second insulating layer 102 is a patterned structure, and a partial top surface 101P of the top surface 101T of the first insulating layer 101 is exposed by the second insulating layer 102. It should be noted that the patterned second insulating layer 102 includes multiple side surfaces 102S, and the side surfaces 102S are connected to the top surface 101T of the first insulating layer 101 and to the top surface 102T of the second insulating layer 102. Accordingly, light from the light-emitting diode 200 (e.g., the light L1 in FIG. 2) may leave the display unit 10 from the side surfaces 102S after passing through the first insulating layer 101 and the second insulating layer 102. In other words, the side surfaces 102S may serve as light-emitting surfaces (i.e., light-emitting surfaces 102S) of the display unit 10.

It should be noted that in a comparative example, the second insulating layer 102 is not a patterned structure, and has a profile 102B′ indicated by a dashed line as shown in FIG. 2, and includes a top surface 102T′ and a side surface 102S′. The light from the light-emitting diode 200 (e.g., the light L1′ in FIG. 2) undergo total internal reflection at the top surface 102T′ and the side surface 102S′, resulting in a decrease in the light extraction efficiency of the light-emitting diode 200. In contrast, the second insulating layer 102 according to the first embodiment of the disclosure is configured as a patterned structure and has multiple light-emitting surfaces 102S connected to the top surface 101T of the first insulating layer 101 and the top surface 102T of the second insulating layer 102. Accordingly, this may prevent the total internal reflection phenomenon in the aforementioned comparative example, thereby improving the light extraction efficiency of the light-emitting diode 200.

Furthermore, in some embodiments, a width T1 of the second insulating layer 102 in the Z direction is greater than a width T2 of the partial top surface 101P exposed by the second insulating layer 102 in the X direction. Accordingly, a larger light-emitting surface 102S may be provided, the above-mentioned effect of the light-emitting surface 102S may be enhanced, and the light extraction efficiency of the light-emitting diode 200 may be improved.

In the display unit 10 shown in FIG. 2, at least a portion of a vertical projection of the top surface 202T of the second semiconductor layer 202 on the substrate SB does not overlap a vertical projection of the second insulating layer 102 on the substrate SB. Accordingly, the first electrode E1 disposed on the top surface 202T of the second semiconductor layer 202 may be exposed from the second insulating layer 102 for electrical bonding.

In order to fully illustrate the various embodiments of the disclosure, other embodiments of the disclosure are described below. It is to be noted that the following embodiments use the reference numerals and a part of the contents of the above embodiments, and the same reference numerals are used to denote the same or similar elements, and the description of the same technical contents is omitted. For the description of the omitted part, reference may be made to the above embodiments, and details are not described in the following embodiments.

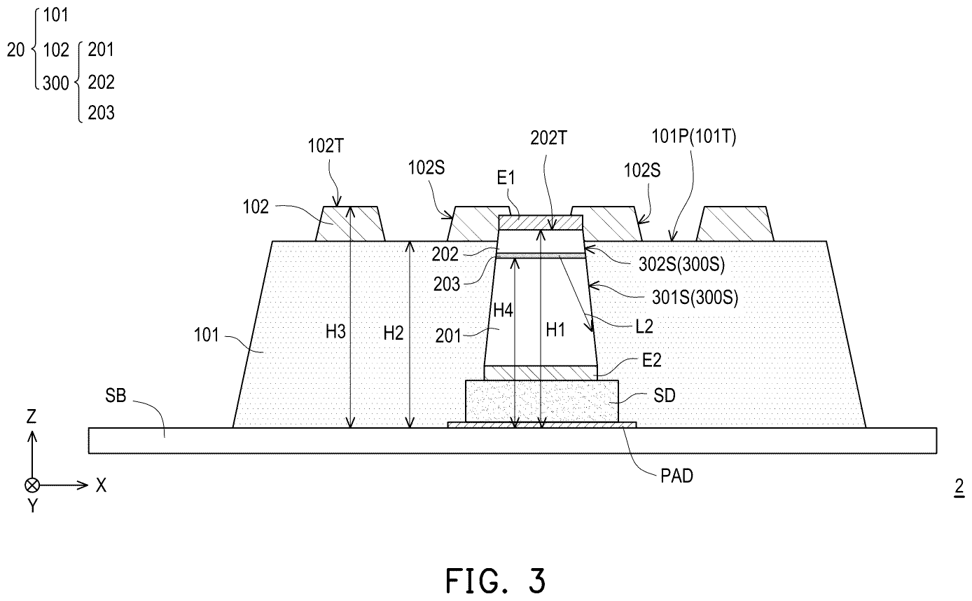

Referring to FIG. 3, FIG. 3 is a schematic diagram showing a display device according to a second embodiment of the disclosure. FIG. 3 may be regarded as a cross-sectional schematic diagram along line segment AA′ of FIG. 1A, FIG. 1B or FIG. 1C.

A display device 2 includes a substrate SB and one or more display units 20 disposed on the substrate SB. The substrate SB is disposed on an X-Y plane. The display unit 20 includes a light-emitting diode 300, a first insulating layer 101 and a second insulating layer 102. The light-emitting diode 300 includes a first semiconductor layer 201, a light-emitting layer 203, and a second semiconductor layer 202 sequentially disposed along the Z direction, and the first semiconductor layer 201 and the second semiconductor layer 202 are an N-type semiconductor and a P-type semiconductor, respectively. The first insulating layer 101 and the second insulating layer 102 directly contact and surround the light-emitting diode 300. A first distance H1 is between a top surface 202T of the second semiconductor layer 202 and the substrate SB, a second distance H2 is between a top surface 101T of the first insulating layer 101 and the substrate SB, and a third distance H3 is between a top surface 102T of the second insulating layer 102 and the substrate SB. The first distance H1 is greater than the second distance H2 and less than the third distance H3.

It should be noted that the first semiconductor layer 201 and the second semiconductor layer 202 of the second embodiment are respectively an N-type semiconductor and a P-type semiconductor, and the thickness of the first semiconductor layer 201 in the Z direction is greater than the thickness of the second semiconductor layer 202 in the Z direction. The side surface 300S of the light-emitting diode 300 includes a first side surface 301S corresponding to the first semiconductor layer 201 and a second side surface 302S corresponding to the second semiconductor layer 202. The area of the first side surface 301S is greater than the area of the second side surface 302S. In this case, light from the light-emitting layer 203 may enter the portion of the first side surface 301S farther away from the light-emitting layer 203 at a greater angle (as shown by the light L2 in FIG. 3), resulting in the occurrence of the total internal reflection phenomenon and reducing the light extraction efficiency of the light-emitting diode 300. Accordingly, the refractive index of the first insulating layer 101 is configured to be greater than the refractive index of the second insulating layer 102 to avoid the above-mentioned total internal reflection phenomenon. In some preferred embodiments, the refractive index of the first insulating layer 101 may be greater than or equal to 1.6. In some embodiments, a fourth distance H4 between the light-emitting layer 203 and the substrate SB is configured to be less than the second distance H2. This ensures that the first side surface 301S may be completely covered by the first insulating layer 101 having a higher refractive index.

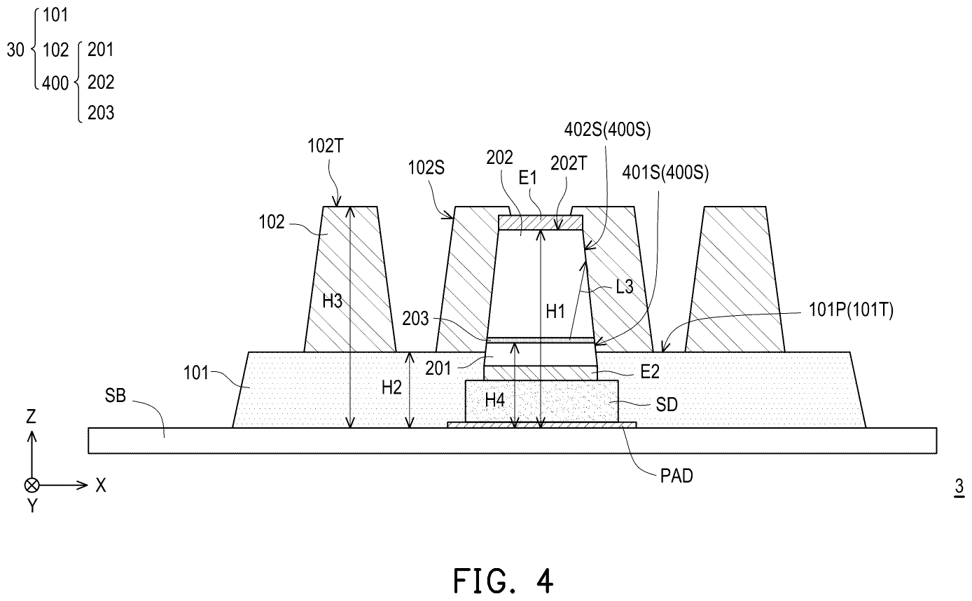

Referring to FIG. 4, FIG. 4 is a schematic diagram showing a display device according to a third embodiment of the disclosure. FIG. 4 may be regarded as a cross-sectional schematic diagram along line segment AA′ of FIG. 1A, FIG. 1B or FIG. 1C.

A display device 3 includes a substrate SB and one or more display units 30 disposed on the substrate SB. The substrate SB is disposed on an X-Y plane. The display unit 30 includes a light-emitting diode 400, a first insulating layer 101 and a second insulating layer 102. The light-emitting diode 400 includes a first semiconductor layer 201, a light-emitting layer 203, and a second semiconductor layer 202 sequentially disposed along the Z direction, and the first semiconductor layer 201 and the second semiconductor layer 202 are a P-type semiconductor and an N-type semiconductor, respectively. The first insulating layer 101 and the second insulating layer 102 directly contact and surround the light-emitting diode 400. A first distance H1 is between a top surface 202T of the second semiconductor layer 202 and the substrate SB, a second distance H2 is between a top surface 101T of the first insulating layer 101 and the substrate SB, and a third distance H3 is between a top surface 102T of the second insulating layer 102 and the substrate SB. The first distance H1 is greater than the second distance H2 and less than the third distance H3.

It should be noted that the first semiconductor layer 201 and the second semiconductor layer 202 of the third embodiment are respectively a P-type semiconductor and an N-type semiconductor, and the thickness of the second semiconductor layer 202 in the Z direction is greater than the thickness of the first semiconductor layer 201 in the Z direction. The side surface 400S of the light-emitting diode 400 includes a first side surface 401S corresponding to the first semiconductor layer 201 and a second side surface 402S corresponding to the second semiconductor layer 202. The area of the second side surface 402S is greater than the area of the first side surface 401S. In this case, light from the light-emitting layer 203 may enter the portion of the second side surface 402S farther away from the light-emitting layer 203 at a greater angle (as shown by the light L3 in FIG. 4), resulting in the occurrence of the total internal reflection phenomenon and reducing the light extraction efficiency of the light-emitting diode 400. Accordingly, the refractive index of the second insulating layer 102 is configured to be greater than the refractive index of the first insulating layer 101 to avoid the above-mentioned total internal reflection phenomenon. In some preferred embodiments, the refractive index of the second insulating layer 102 may be greater than or equal to 1.6. In some embodiments, the fourth distance H4 between the light-emitting layer 203 and the substrate SB is configured to be greater than the second distance H2. This ensures that the second side surface 402S may be completely covered by the second insulating layer 102 having a higher refractive index, thereby improving the light extraction efficiency of the light-emitting diode 400.

In summary, the display device provided according to the embodiment of the disclosure has at least the following features and advantages. (1) The first insulating layer and the second insulating layer are configured to directly contact the side surface of the light-emitting diode to avoid the occurrence of total internal reflection at the light-emitting surface of the light-emitting diode. (2) When the refractive indexes of the first insulating layer, the second insulating layer and the air gradually decrease in that order, the interface between the first insulating layer and the second insulating layer may be used to improve the light extraction efficiency of the light-emitting diode. (3) Multiple side surfaces of the second insulating layer may serve as light-emitting surfaces of the display unit to further improve the light extraction efficiency of the light-emitting diode. (4) When the thicknesses of the first semiconductor layer and the second semiconductor layer are different, an insulating layer with a higher refractive index is configured to correspond to the semiconductor layer with a larger thickness to improve the light extraction efficiency of the light-emitting diode. (5) The luminous intensity of the display device increases by 15.2% in the front viewing angle direction, and the gain at all viewing angles increases by an average of 7.4%.

What is claimed is:

1. A display device, comprising a substrate and a plurality of display units disposed on the substrate, at least one display unit among the display units comprising:
a light-emitting diode, comprising a first semiconductor layer, a light-emitting layer and a second semiconductor layer sequentially disposed along a first direction away from the substrate;
a first insulating layer, surrounding the light-emitting diode; and
a second insulating layer, surrounding the light-emitting diode, wherein the first insulating layer is disposed between the substrate and the second insulating layer,
wherein a first distance between a top surface of the second semiconductor layer and the substrate is greater than a second distance between a top surface of the first insulating layer and the substrate, and is less than a third distance between a top surface of the second insulating layer and the substrate.

2. The display device according to claim 1, wherein the second insulating layer is a patterned structure, and a partial top surface in the top surface of the first insulating layer is exposed by the second insulating layer.

3. The display device according to claim 2, wherein a width of the second insulating layer in the first direction is greater than a width of the partial top surface exposed by the second insulating layer in a second direction, the second direction is perpendicular to the first direction.

4. The display device according to claim 1, wherein the second insulating layer directly contacts the top surface of the first insulating layer, a refractive index of the second insulating layer is less than a refractive index of the first insulating layer and is greater than 1.

5. The display device according to claim 1, wherein at least a portion of a vertical projection of the top surface of the second semiconductor layer on the substrate does not overlap a vertical projection of the second insulating layer on the substrate.

6. The display device according to claim 1, wherein the second semiconductor layer comprises at least one side surface, the at least one side surface is connected to the top surface of the first insulating layer and connected to the top surface of the second insulating layer.

7. The display device according to claim 6, wherein the at least one side surface is formed as a light-emitting surface of the display unit.

8. The display device according to claim 1, wherein the first insulating layer and the second insulating layer directly contact the light-emitting diode.

9. The display device according to claim 8, wherein the first semiconductor layer and the second semiconductor layer are respectively an N-type semiconductor and a P-type semiconductor, and a refractive index of the first insulating layer is greater than a refractive index of the second insulating layer.

10. The display device according to claim 9, wherein the refractive index of the first insulating layer is greater than or equal to 1.6.

11. The display device according to claim 9, wherein a fourth distance between the light-emitting layer and the substrate is less than the second distance.

12. The display device according to claim 8, wherein the first semiconductor layer and the second semiconductor layer are respectively a P-type semiconductor and an N-type semiconductor, and a refractive index of the second insulating layer is greater than a refractive index of the first insulating layer.

13. The display device according to claim 12, wherein the refractive index of the second insulating layer is greater than or equal to 1.6.

14. The display device according to claim 12, wherein a fourth distance between the light-emitting layer and the substrate is greater than the second distance.

15. A display device, comprising a substrate and a plurality of display units disposed on the substrate, at least one display unit among the display units comprising:
a light-emitting diode, comprising a first semiconductor layer, a light-emitting layer and a second semiconductor layer sequentially disposed along a first direction away from the substrate;
a first insulating layer, surrounding the light-emitting diode; and
a second insulating layer, surrounding the light-emitting diode, wherein the first insulating layer is disposed between the substrate and the second insulating layer,
wherein the second insulating layer is a patterned structure, and a partial top surface in a top surface of the first insulating layer is exposed by the second insulating layer, and
wherein the second insulating layer directly contacts the top surface of the first insulating layer, a refractive index of the second insulating layer is less than a refractive index of the first insulating layer and is greater than 1.

16. The display device according to claim 15, wherein a first distance between a top surface of the second semiconductor layer and the substrate is greater than a second distance between the top surface of the first insulating layer and the substrate, and is less than a third distance between a top surface of the second insulating layer and the substrate.

17. The display device according to claim 15, wherein a width of the second insulating layer in the first direction is greater than a width of the partial top surface exposed by the second insulating layer in a second direction, the second direction is perpendicular to the first direction.

18. The display device according to claim 16, wherein at least a portion of a vertical projection of the top surface of the second semiconductor layer on the substrate does not overlap a vertical projection of the second insulating layer on the substrate.

19. The display device according to claim 16, wherein the second semiconductor layer comprises at least one side surface, the at least one side surface is connected to the top surface of the first insulating layer and connected to the top surface of the second insulating layer.

20. The display device according to claim 19, wherein the at least one side surface is formed as a light-emitting surface of the display unit.
